(19) United States
(12) Patent Application Publication
(10) Pub. No.: US 2002/0180495 A1
(43) Pub. Date: Dec. 5, 2002

(54) CMOS output circuit

(75) Inventor: Toshiaki Motoyui, Ohtsu-shi (JP)

Correspondence Address: YOUNG & THOMPSON, 745 SOUTH 23RD STREET 2ND FLOOR, ARLINGTON, VA, 22202

(73) Assignee: NEC CORPORATION, TOKYO (JP)

(21) Appl. No.: 10/156,833

(22) Filed: May 30, 2002

(30) Foreign Application Priority Data
May 30, 2001 (JP) 2001-161879

(51) Int. Cl. H03B 1/00

(52) U.S. Cl. 327/108

(57) ABSTRACT

When a rise of an input signal Vin is applied to an input terminal, an output of a two-input NAND circuit changes to the “H” level, and an output MOS transistor is controlled to turn off. In this state, a sense MOS transistor is simultaneously controlled to turn off, the electric potential of a drain of the sense MOS transistor is pulled down, an output of a two-input NOR circuit changes to the “H” level, and an output MOS transistor is controlled to turn on. When a fall of the input signal Vin is applied to the input terminal, the output of two-input NOR circuit changes to the “L” level, and the output MOS transistor is controlled to turn off. In this state, a sense MOS transistor is simultaneously controlled to turn off, the electric potential of a drain of the sense MOS transistor is pulled up, and the output of two-input NAND circuit changes to the “L” level, and the output MOS transistor is controlled to turn on.

### BACK GROUND OF THE INVENTION

1. Technical Field of the Invention

The present invention relates to a CMOS output circuit.

2. Description of the Related Art

A conventional CMOS output circuit is constituted by a serially connected circuit of a P-channel output MOS transistor and an N-channel output MOS transistor. When the P-channel output MOS transistor and N-channel output MOS transistor turn on simultaneously in the CMOS output circuit, a shot-through current flows.

The following section describes a conventional CMOS output circuit which prevents the shot-through current while referring to FIG. 1. A numeral 1 indicates an input terminal, a numeral 2 indicates an output terminal, a numeral 3 indicates a power supply terminal, and a numeral 4 indicates a ground terminal in the drawing. A P-channel output MOS transistor 5 and an N-channel output MOS transistor 6 are serially connected between the power supply terminal 3 and the ground terminal 4, and a point where the output MOS transistor 5 and the output MOS transistor 6 are connected with each other is connected with the output terminal 2. Delay circuits 9 and 10 are respectively connected with gates of the output MOS transistors 5 and 6 through pre-drivers 7 and 8. Both of input terminals of the delay circuits 9 and 10 are connected with the input terminal 1. The delay circuit 9 delays a fall of the input signal Vin supplied from the input terminal 1, and the delay circuit 10 delays a rise of the input signal Vin supplied from the input terminal 1.

As shown in FIG. 2, when the rise of input signal Vin is applied to the input terminal 1 at time t1, a gate voltage Vpg becomes the “H” level at time t2 after an off-switching time, and the output MOS transistor 5 is controlled to turn off. A gate voltage Vng becomes the “H” level at the time t4 after a predetermined delay from the time t1 to t3 (>t2) set by the delay circuit 10, and an on-switching time, and the output MOS transistor 6 is controlled to turn on. When the fall of input signal Vin is applied to the input terminal 1 at time t5, the gate voltage Vng becomes the “L” level at time t6 after an off-switching time, and the output MOS transistor 6 is controlled to turn off, and the gate voltage Vpg becomes the “L” level at time t8 after a predetermined delay set by the delay circuit 9 from time t5 to time t7 (>t6) to, and an on-switching time, and the output MOS transistor 5 is controlled to turn on.

The delay circuit 10 delays the rise of gate of output MOS transistor 6, the delay circuit 9 delays the fall of gate of output MOS transistor 5, a high impedance period (a dead time) is provided on the output terminal 2 between the time t2 and t3, and between t6 and t7, and a shot-through current is prevented in the CMOS output circuit shown in FIG. 1. Inverters generally constitute the delay circuits 9 and 10, and it is necessary to connect multiple stages of the inverters to properly set the delay times, if the delay time is too short, the insufficient dead time causes an insufficient prevention of the shot-through current, if the delay time is too long, the excessive dead time causes a degraded input/output response, and there is such a problem as it is difficult to set proper times. There is another problem that a variation of the delay circuits 9 and 10 in manufacturing causes a variation in the input/output response.

The following section describes another example of the conventional CMOS output circuit while referring to FIG. 3. A numeral 1 indicates an input terminal, a numeral 2 indicates an output terminal, a numeral 3 indicates a power supply terminal, and a numeral 4 indicates a ground terminal in the drawing. A P-channel output MOS transistor 5 and an N-channel output MOS transistor 6 are serially connected between the power supply terminal 3 and the ground terminal 4, and a point where the output MOS transistor 5 and the output MOS transistor 6 are connected with each other is connected with the output terminal 2. A two-input NAND circuit 11 is connected with a gate of the output MOS transistor 5 through a pre-driver 7, and a two-input NOR circuit 12 is connected with a gate of the output MOS transistor 6 through a pre-driver 8. One input terminal of the two-input NAND circuit 11, and one input terminal of the two-input NOR circuit 12 are connected with the input terminal 1 through an inverter 13. The gate of output MOS transistor 6 is connected with the other input terminal of two-input NAND circuit 11 through the delay circuit 9 and an inverter 14. The gate of output MOS transistor 5 is connected with the other input terminal of two-input NOR circuit 12 through the delay circuit 10 and an inverter 15.

When a rise of an input signal Vin is applied to the input terminal 1 at time t1, an output of the inverter 13 becomes the “L” level, a gate voltage Vpg becomes the “H” level at time t2 after an off-switching time, and the output MOS transistor 5 is controlled to turn off as shown in FIG. 4. When the gate voltage Vpg of output MOS transistor 5 becomes the “H” level, an output Vnde of the delay circuit 10 becomes the “L” level at time t3 (>t2) after a delay time set by the delay circuit 10 through an inversion by the inverter 15, a gate voltage Vng becomes the “H” at time t4 after an on-switching time, and the output MOS transistor 6 is controlled to turn on. When a fall of the input signal Vin is applied to the input terminal 1 at time t5, the output of inverter 13 becomes the “H” level, the gate voltage Vng becomes the “L” level at time t6 after an off-switching time, and the output MOS transistor 6 is controlled to turn off. When the gate voltage Vng of output MOS transistor 6 becomes the “L” level, an output Vpde of the delay circuit 9 becomes the “H” level at time t7 (>t6) after a delay time set by the delay circuit 9 through an inversion by the inverter 14, the gate voltage Vpg becomes the “L” at time t8 after an on-switching time, and the output MOS transistor 5 is controlled to turn on.

When the inverter 15 switches on the output MOS transistor 6 just after it detects that the gate voltage Vpg of output MOS transistor 5 becomes the “H” level, and the inverter 14 switches on the output MOS transistor 5 just after it detects that the gate voltage Vng of output transistor 6 becomes the “L” level, it is possible to prevent the shot-through current without the dead time in the CMOS output circuit shown in FIG. 3 without providing the delay circuits 9 and 10. However, if there is a manufacturing variation in threshold voltages of the two-input NAND circuit 11, and the two-input NOR circuit 12, and the inverters 14 and 15 in this case, because the two-input NOR circuit 12 may detect the “L” level from the inverter 15, and switch the output to the “H” level before the gate voltage Vpg of output MOS transistor 5 sufficiently becomes the “H” level, or the two-input NAND circuit 11 may detect the “H” level from the inverter 14, and switch the output to the “L” level before the gate voltage Vng of output MOS transistor 6 sufficiently becomes the “L” level, it is necessary to provide the delay circuits 9 and 10, and to set the delay time to proper times for preventing these problems. In this case, there are such problems as when the delay times of delay circuits 9 and 10 are too short, the prevention of shot-through current is insufficient, when the delay time is too long, the input/output response is degraded, and there is a variation in the input/output response as in the CMOS output circuit in FIG. 1.

The conventional CMOS output circuits shown in FIG. 1 and FIG. 3 cannot sufficiently prevent the shot-through current without degrading the input/output response and the variation in input/output response as described above.

### SUMMARY OF THE INVENTION

The purpose of the present invention is to provide a CMOS output circuit for preventing a shot-through current without delay circuits.

A P-channel output MOS transistor and an N-channel output MOS transistor are serially connected, and an output signal is provided from a serially connected point when an input signal is applied to gates in the CMOS output circuit of the present invention, and the CMOS output circuit is characterized in that the N-channel output MOS transistor is controlled to turn on after it is determined that the P-channel output MOS transistor is turned off based on a state where a P-channel sense MOS transistor having characteristics similar to those of the P-channel output MOS transistor is turned off, and the P-channel output MOS transistor is controlled to turn on after it is determined that the N-channel output MOS transistor is turned off based on a state where an N-channel sense MOS transistor having characteristics similar to those of the N-channel output MOS transistor is turned off.

### BRIEF DESCRIPTION OF THE DRAWINGS

FIG. 1 is a circuit diagram for showing a conventional CMOS output circuit;

FIG. 2 is a timing chart for describing the operation of CMOS output circuit in FIG. 1;

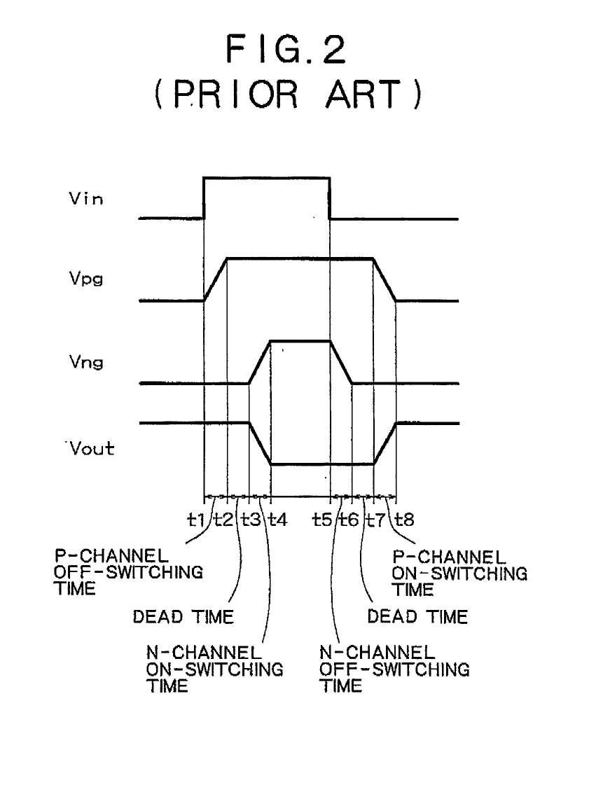

FIG. 3 is a circuit diagram for showing an alternative example of the conventional CMOS output circuit;

FIG. 4 is a timing chart for describing the operation of CMOS output circuit in FIG. 3;

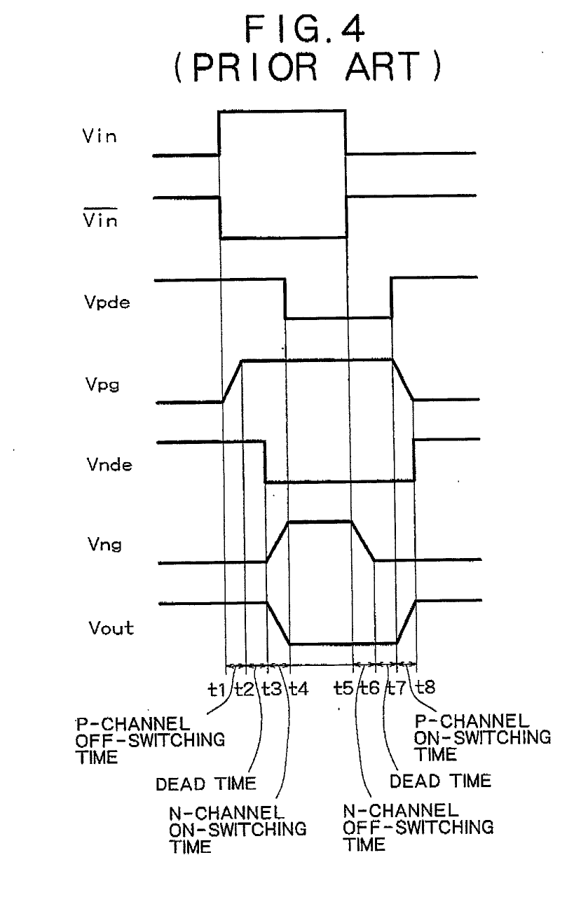

FIG. 5 is a circuit diagram for showing a CMOS output circuit of a first embodiment of the present invention; and

FIG. 6 is a timing chart for describing the operation of CMOS output circuit in FIG. 5.

### DETAILED DESCRIPTION OF THE PREFERRED EMBODIMENTS

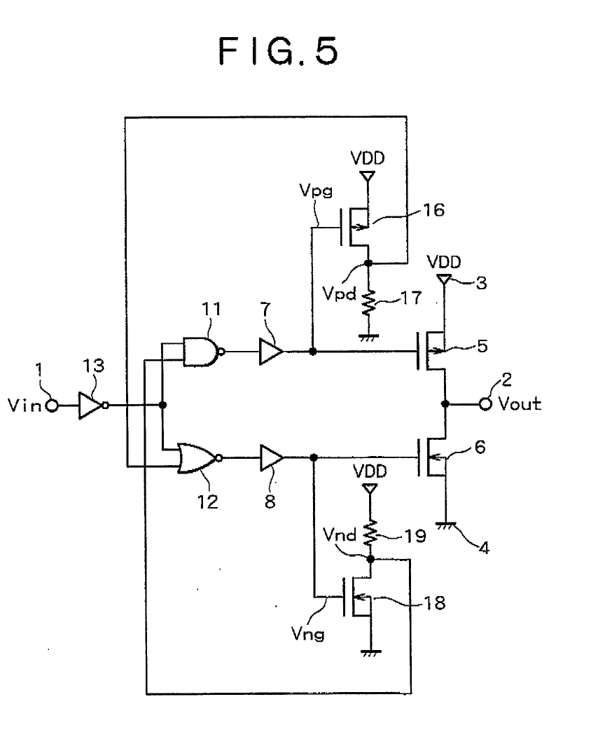

The following section describes a first embodiment of the present invention while referring to FIG. 5. A numeral 1 indicates an input terminal, a numeral 2 indicates an output terminal, a numeral 3 indicates a power supply terminal, and a numeral 4 indicates a ground terminal in the drawing. A P-channel output MOS transistor 5 and an N-channel output MOS transistor 6 are serially connected between the power supply terminal 3 and the ground terminal 4, and a point where the output MOS transistor 5 and the output MOS transistor 6 are connected with each other is connected with the output terminal 2. A two-input NAND circuit 11 is connected with a gate of the output MOS transistor 5 through a pre-driver 7, and a two-input NOR circuit 12 is connected with a gate of the output MOS transistor 6 through a pre-driver 8. One input terminal of the two-input NAND circuit 11, and one input terminal of the two-input NOR circuit 12 are connected with the input terminal 1 through an inverter 13. A P-channel sense MOS transistor 16 having characteristics similar to those of the output MOS transistor 5, and a pull-down resistor 17 are serially connected between the power supply terminal 3 and the ground terminal 4, and an N-channel sense MOS transistor 18 having characteristics similar to those of the output MOS transistor 6, and a pull-up resistor 19 are serially connected between the power supply terminal 3 and the ground terminal 4. The gate of sense MOS transistor 16 is connected with the gate of output MOS transistor 5, and the drain is connected with the other input terminal of two-input NOR circuit 12. The gate of sense MOS transistor 18 is connected with the gate of output MOS transistor 6, and the drain is connected with the other input terminal of two-input NAND circuit 11. Because the sense MOS transistors 16 and 18 respectively have the characteristics similar to those of the output MOS transistors 5 and 6, they are formed on the same substrate with a different channel width and the same channel length.

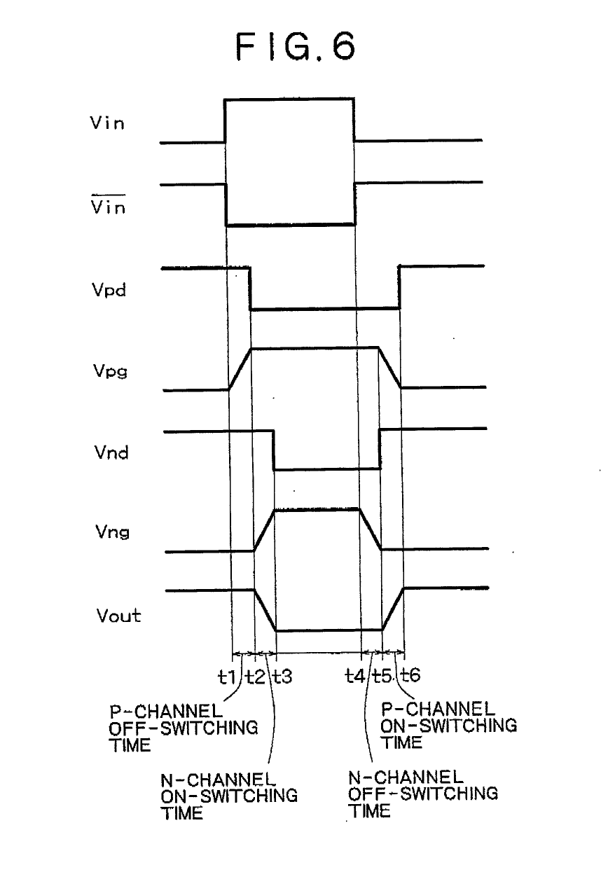

As shown in FIG. 6, when a rise of an input signal Vin is applied to the input terminal 1 at time t1, the output of inverter 13 becomes the “L” level, a gate voltage Vpg becomes the “H” level at time t2 after an off-switching time, and the output MOS transistor 5 is controlled to turn off as shown in FIG. 6. Because the sense MOS transistor 16 is formed such that its characteristics are similar to those of the output MOS transistor 5, it has the same threshold voltage, and because its gate is connected with that of the output MOS transistor 5, they are controlled to turn off simultaneously, and a drain electric potential Vpd of the sense MOS transistor 16 is pulled down to the “L” level. When the drain electric potential Vpd at the “L” level is applied to the two-input NOR circuit 12, the gate voltage Vng becomes the “H” level at time t3 after an on-switching time, and the output MOS transistor 6 is controlled to turn on. When a fall of the input signal Vin is applied to the input terminal 1 at time t4, the output of inverter 13 becomes the “H” level, the gate voltage Vng becomes the “L” level at time t5 after an off-switching time, and the output MOS transistor 6 is controlled to turn off. Because the sense MOS transistor 18 is formed such that its characteristics are similar to those of the output MOS transistor 6, it has the same threshold voltage, and because its gate is connected with that of the output MOS transistor 6, they are controlled to turn off simultaneously, and a drain electric potential Vnd of the sense MOS transistor 18 is pulled up to the “H” level. When the drain electric potential Vnd at the “H” level is applied to the two-input NAND circuit 11, the gate voltage Vpg becomes the “L” level at time t6 after an on-switching time, and the output MOS transistor 5 is controlled to turn on.

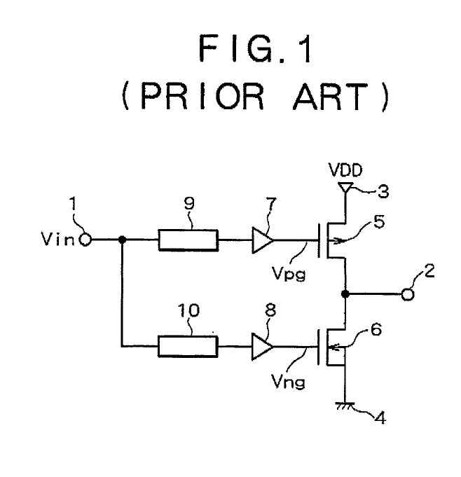

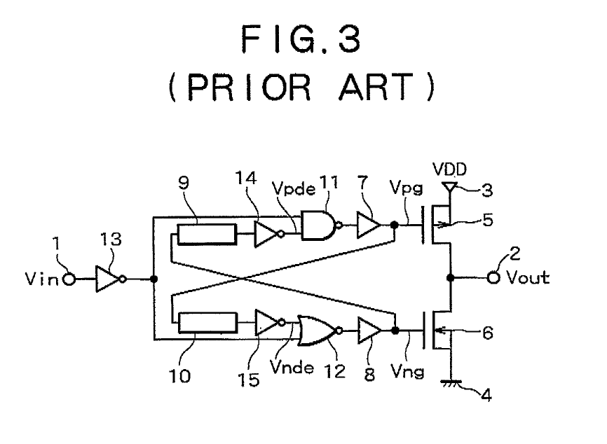

As described above, the CMOS output circuit of the present embodiment shown in FIG. 5 determines that the gate voltage Vpg of output MOS transistor 5 becomes the “H” level, and the output MOS transistor 5 is controlled to turn off based on a state that the sense MOS transistor 16 is controlled to turn off, changes the gate voltage Vng of output MOS transistor 6 to the “H” level after the drain of sense MOS transistor 16 becomes the “L” level, and controls the output MOS transistor 6 turn on. The CMOS output circuit determines that the gate voltage Vng of output MOS transistor 6 becomes the “L” level, and the output MOS transistor 6 is controlled to turn off based on a state that the sense MOS transistor 18 is controlled to turn off, changes the gate voltage Vpg of output MOS transistor 5 to the “L” level after the drain of sense MOS transistor 18 becomes the “H” level, and controls the output MOS transistor 5 turn on. With this constitution, the period where the output MOS transistors 5 and 6 are turned on simultaneously without a delay circuit is eliminated, the shot-through current is prevented, and necessity of designing the delay circuit is eliminated. As a result, such problems as the shot-through current is not sufficiently prevented when the delay time is too short, the input/output response is degraded when the delay time is too long, and the variation in manufacturing the delay circuit varies the input/output response as in the CMOS output circuits shown in FIG. 1 and FIG. 3 are solved.

As described above, with the CMOS output circuit of the present invention, after it is determined that the P-channel output MOS transistor is controlled to turn off based on the state where the P-channel sense MOS transistor whose characteristics are similar to those of the P-channel output MOS transistor is controlled turn off, the N-channel output MOS transistor is controlled to turn on, and after it is determined that the N-channel output MOS transistor is controlled to turn off based on the state where the N-channel sense MOS transistor whose characteristics are similar to those of the N-channel output MOS transistor is controlled turn off, the P-channel output MOS transistor is controlled to turn on. As a result, the switching for on/off control for P-channel output MOS transistor, and for on/off control for N-channel output MOS transistor is optimally set without providing delay circuits where it is difficult to optimally design the delay time, and this constitution prevents the shot-through current.

What is claimed is:

1. A CMOS output circuit comprising:
a P-channel output MOS transistor and an N-channel output MOS transistor serially connected with each other;
an output terminal connected with a point where the P-channel output MOS transistor and the N-channel output MOS transistor are connected with each other, and providing an output signal;
an input terminal; and
a control circuit connected between individual gates of said P-channel output MOS transistor and said N-channel output MOS transistor, and said input terminal, said control circuit having:
a P-channel sense MOS transistor having characteristics similar to those of said P-channel output MOS transistor;
an N-channel sense MOS transistor having characteristics similar to those of said N-channel output MOS transistor; and
a determination circuit for controlling said N-channel output MOS transistor turn on after it determines that said P-channel output MOS transistor is turned off based on a state where said P-channel sense MOS transistor is turned off, and controlling said P-channel output MOS transistor turn on after it determines that said N-channel output MOS transistor is turned off based on a state where said N-channel sense MOS transistor is turned off.

2. The CMOS output circuit according to claim 1, wherein gates of said P-channel output MOS transistor and P-channel sense MOS transistor are connected with each other, and a drain of the P-channel sense MOS transistor is pulled down to determine that said P-channel output MOS transistor is turned off based on said P-channel sense MOS transistor, and gates of said N-channel output MOS transistor and N-channel sense MOS transistor are connected with each other, and a drain of the N-channel sense MOS transistor is pulled up to determine that said N-channel output MOS transistor is turned off based on said N-channel sense MOS transistor in said determination circuit.

3. The CMOS output circuit according to claim 2, wherein said determination circuit comprises a first two-input logic circuit which provides an on-control signal for said P-channel output MOS transistor based on said input signal, and a pull-up signal of the drain of said N-channel sense MOS transistor, and a second two-input logic circuit which provides an on-control signal for said N-channel output MOS transistor based on said input signal, and a pull-down signal of the drain of said P-channel sense MOS transistor.
